(19) United States
(12) Patent Application Publication
(10) Pub. No.: US 2025/0081689 A1
(43) Pub. Date: Mar. 6, 2025

(54) WIRE GRID POLARIZATION STRUCTURE FOR CURRENT SPREADING AND POLARIZATION CONTROL

(71) Applicant: CreeLED, Inc., Durham, NC (US)

(72) Inventors: David Suich, Durham, NC (US); Michael Check, Holly Springs, NC (US); Austin Spencer, Durham, NC (US); Colin Blakely, Raleigh, NC (US)

(21) Appl. No.: 18/239,145

(22) Filed: Aug. 29, 2023

(51) Int. Cl. H01L 33/58; G02B 5/30

(52) U.S. Cl. CPC H10H 20/855; G02B 5/3058; H10H 20/0363

(57) ABSTRACT

Solid-state lighting devices, and more particularly, wire grid polarization structure for current spreading and polarization control for light emitting diode (LED) package, and a method for making the same are disclosed. The wire grid polarization structure can be configured to both polarize light emitted by an LED chip of the LED package as well as spread current on a layer of the LED chip, resulting in more even light emission across the LED chip. The wire grid polarization structure can be formed on a top surface of the LED chip, and be electrically coupled to an electrode to spread the current across the top surface of the LED chip. In an embodiment, the wire grid polarization structure can include interdigitated fingers that are coupled to both an anode and an electrode.

### FIELD OF THE DISCLOSURE

The present disclosure relates to a solid-state lighting device, and more particularly to a wire grid polarization structure for current spreading and polarization control for light emitting diode (LED) package.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs have enabled a variety of new display applications and are being increasingly utilized for general illumination and automotive applications, often replacing incandescent and fluorescent light sources.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. An LED chip typically includes an active region that may be fabricated, for example, from silicon carbide, gallium nitride, gallium phosphide, aluminum nitride, gallium arsenide-based materials, and/or from organic semiconductor materials. Photons generated by the active region are initiated in all directions.

The art continues to seek improved LEDs and solid-state lighting devices having desirable illumination characteristics capable of overcoming challenges associated with conventional lighting devices.

### SUMMARY

The present disclosure relates to a solid-state lighting device, and more particularly to a wire grid polarization structure for current spreading and polarization control for light emitting diode (LED) package, and a method for making the same. The wire grid polarization structure can be configured to both polarize light emitted by an LED chip of the LED package as well as spread current on a layer of the LED chip, resulting in more even light emission across the LED chip. The wire grid polarization structure can be formed on a top surface of the LED chip, and be electrically coupled to an electrode to spread the current across the top surface of the LED chip. In an embodiment, the wire grid polarization structure can include interdigitated fingers that are coupled to both an anode and an electrode.

In an embodiment, an LED package can include a submount, an LED chip on the submount, a first electrode that delivers current to a top surface of the LED chip, and a wire grid polarization structure, electrically coupled to the first electrode, that is on the top surface of the LED chip, wherein the wire grid polarization structure is configured so that unpolarized light generated by the LED chip is received by the wire grid polarization structure and polarized light exits the wire grid polarization structure.

In an embodiment, the wire grid polarization structure is configured to be a current spreading layer.

In an embodiment, the LED package further includes a second electrode that delivers current to the top surface of the LED chip, wherein the first electrode is electrically coupled to a first portion of the wire grid polarization structure, and the second electrode is electrically coupled to a second portion of the wire grid polarization structure.

In an embodiment, wires of the first portion of the wire grid polarization structure and wires of the second portion of the wire grid polarization structure are interdigitated.

In an embodiment, the wire grid polarization structure preferentially transmits light emitted from the LED chip that is polarized along a first direction relative to light polarized along other directions, wherein the first direction is based on an orientation of the wire grid polarization structure.

In an embodiment, the first electrode is electrically coupled to the wire grid polarization structure via a wire bond.

In an embodiment, the wire grid polarization structure is bonded to the top surface of the LED chip by an adhesion layer that is formed of at least one of chrome or titanium.

In an embodiment, wires of the wire grid polarization layer comprise at least one of aluminum, silver, or gold.

In an embodiment, wires of the wire grid polarization layer comprise at least two of aluminum, silver, or gold, wherein a ratio of the metals is predetermined based on a polarization selectivity.

In an embodiment, wires of the wire grid polarization layer comprise at least two of aluminum, silver, or gold, wherein a ratio of the metals is predetermined based on a wavelength of light emitted by the LED chip.

In an embodiment, the LED package can include a passivation layer covering the wire grid polarization structure.

In an embodiment, wires of the wire grid polarization structure have a cross-sectional diameter less than 1 micron.

In an embodiment, a method for forming an LED package can include attaching an LED chip to a submount, smoothing a top surface of the LED chip, and attaching a wire grid polarization structure to the top surface of the LED chip and electrically coupling the wire grid polarization structure to a first electrode, that is on the top surface of the LED chip, wherein the wire grid polarization structure is configured so that unpolarized light generated by the LED chip is received by the wire grid polarization structure and polarized light exits the wire grid polarization structure.

In an embodiment, the wire grid polarization structure is configured to be a current spreading layer.

In an embodiment, a first portion of the wire grid polarization structure is electrically coupled to the first electrode, and wherein the method further comprises electrically coupling a second portion of the wire grid polarization structure to a second electrode that delivers current to the top surface of the LED chip.

In an embodiment, the method further includes forming the wire grid polarization structure from at least one of aluminum, silver, or gold.

In an embodiment, the method further includes forming the wire grid polarization structure from at least two of aluminum, silver, or gold, wherein a ratio of the metals is predetermined based on a polarization selectivity or a wavelength of light emitted by the LED chip.

In an embodiment, the method further includes applying an adhesion layer of chrome or titanium to the top surface of the LED chip before attaching the wire grid polarization structure.

In an embodiment, the method further includes forming a passivation layer around the wire grid polarization structure.

In an embodiment, a LED device includes an LED chip, a first electrode that delivers current to a top surface of the LED chip, and a wire grid polarization structure, electrically coupled to the first electrode, that is on the top surface of the LED chip, wherein the wire grid polarization structure is configured so that unpolarized light generated by the LED chip is received by the wire grid polarization structure and polarized light exits the wire grid polarization structure.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is an exemplary cross-sectional diagram of a light emitting diode (LED) package with a wire grid polarization structure according to one or more embodiments of the present disclosure.

FIG. 2 is an exemplary top view of a wire grid polarization structure coupled to a single electrode according to one or more embodiments of the present disclosure.

FIGS. 3A and 3B are exemplary top views of a wire grid polarization structure coupled to two electrodes according to one or more embodiments of the present disclosure.

FIG. 4 is an exemplary top view of another wire grid polarization structure coupled to a single electrode according to one or more embodiments of the present disclosure.

FIG. 5A is an exemplary isometric view of a lateral die LED with two electrodes according to one or more embodiments of the present disclosure.

FIG. 5B is an exemplary top view of a wire grid polarization structure in the embodiment from FIG. 5A according to one or more embodiments of the present disclosure.

FIGS. 6A-6D are exemplary cross-sectional views of various embodiments of wire grid polarization structure wires according to one or more embodiments of the present disclosure.

FIGS. 7A-7C are diagrams depicting planarization of an LED chip surface and wire grid polarization structure formation according to one or more embodiments of the present disclosure.

FIG. 8 is a flowchart of a method for forming an LED package with a wire grid polarization structure according to one or more embodiments of the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to a solid-state lighting device, and more particularly to a wire grid polarization structure for current spreading and polarization control for light emitting diode (LED) package, and a method for making the same. The wire grid polarization structure can be configured to both polarize light emitted by an LED chip of the LED package as well as spread current on a layer of the LED chip, resulting in more even light emission across the LED chip. The wire grid polarization structure can be formed on a top surface of the LED chip, and be electrically coupled to an electrode to spread the current across the top surface of the LED chip. In an embodiment, the wire grid polarization structure can include interdigitated fingers that are coupled to both an anode and an electrode.

An LED chip typically comprises an active LED structure or region that can have many different semiconductor layers arranged in different ways. The fabrication and operation of LEDs and their active structures are generally known in the art and are only briefly discussed herein. The layers of the active LED structure can be fabricated using known processes with a suitable process being fabrication using metal organic chemical vapor deposition. The layers of the active LED structure can comprise many different layers and generally comprise an active layer sandwiched between n-type and p-type oppositely doped epitaxial layers, all of which are formed successively on a growth substrate. It is understood that additional layers and elements can also be included in the active

LED structure, including, but not limited to, buffer layers, nucleation layers, super lattice structures, un-doped layers, cladding layers, contact layers, and current-spreading layers and light extraction layers and elements. The active layer can comprise a single quantum well, a multiple quantum well, a double heterostructure, or super lattice structures.

The active LED structure can be fabricated from different material systems, with some material systems being Group III nitride-based material systems. Group III nitrides refer to those semiconductor compounds formed between nitrogen (N) and the elements in Group III of the periodic table, usually aluminum (Al), gallium (Ga), and indium (In). Gallium nitride (GaN) is a common binary compound. Group III nitrides also refer to ternary and quaternary compounds such as aluminum gallium nitride (AlGaN), indium gallium nitride (InGaN), and aluminum indium gallium nitride (AlInGaN). For Group III nitrides, silicon (Si) is a common n-type dopant and magnesium (Mg) is a common p-type dopant. Accordingly, the active layer, n-type layer, and p-type layer may include one or more layers of GaN, AlGaN, InGaN, and AlInGaN that are either undoped or doped with Si or Mg for a material system based on Group III nitrides. Other material systems include silicon carbide (SiC), organic semiconductor materials, and other Group III-V systems such as gallium phosphide (GaP), gallium arsenide (GaAs), and related compounds.

The active LED structure may be grown on a growth substrate that can include many materials, such as sapphire, SiC, aluminum nitride (AlN), and GaN. Sapphire is another common substrate for Group III nitrides and also has certain advantages, including being lower cost, having established manufacturing processes, and having good light-transmissive optical properties.

Different embodiments of the active LED structure can emit different wavelengths of light depending on the composition of the active layer. In some embodiments, the active LED structure emits blue light with a peak wavelength range of approximately 430 nanometers (nm) to 480 nm. In other embodiments, the active LED structure emits green light with a peak wavelength range of 500 nm to 570 nm. In other embodiments, the active LED structure emits red light with a peak wavelength range of 600 nm to 650 nm. In certain embodiments, the active LED structure may be configured to emit light that is outside the visible spectrum, including one or more portions of the ultraviolet (UV) spectrum, or one or more portions of the near infrared spectrum, and/or the infrared spectrum (e.g., 700 nm to 1000 nm). The UV spectrum is typically divided into three wavelength range categories denotated with letters A, B, and C. In this manner, UV-A light is typically defined as a peak wavelength range from 315 nm to 400 nm, UV-B is typically defined as a peak wavelength range from 280 nm to 315 nm, and UV-C is typically defined as a peak wavelength range from 100 nm to 280 nm. UV LEDs are of particular interest for use in applications related to the disinfection of microorganisms in air, water, and surfaces, among others. In other applications, UV LEDs may also be provided with one or more lumiphoric materials to provide LED packages with aggregated emissions having a broad spectrum and improved color quality for visible light applications.

An LED chip can also be covered with one or more lumiphoric materials (also referred to herein as lumiphors), such as phosphors, such that at least some of the light from the LED chip is absorbed by the one or more lumiphors and is converted to one or more different wavelength spectra according to the characteristic emission from the one or more lumiphors. In this regard, at least one lumiphor receiving at least a portion of the light generated by the LED source may re-emit light having different peak wavelength than the LED source. An LED source and one or more lumiphoric materials may be selected such that their combined output results in light with one or more desired characteristics such as color, color point, intensity, etc. In certain embodiments, aggregate emissions of LED chips, optionally in combination with one or more lumiphoric materials, may be arranged to provide cool white, neutral white, or warm white light, such as within a color temperature range of from 2500K to 10,000K. In certain embodiments, lumiphoric materials having cyan, green, amber, yellow, orange, and/or red peak emission wavelengths may be used. In some embodiments, the combination of the LED chip and the one or more lumiphors (e.g., phosphors) emits a generally white combination of light. The one or more phosphors may include yellow (e.g., YAG:Ce), green (e.g., LuAg:Ce), and red (e.g., Ca_{i-x-y}SrₓEu_{y}AlSiN₃) emitting phosphors, and combinations thereof.

Lumiphoric materials as described herein may be or include one or more of a phosphor, a scintillator, a lumiphoric ink, a quantum dot material, a day glow tape, and the like. Lumiphoric materials may be provided by any suitable means, for example, direct coating on one or more surfaces of an LED, dispersal in an encapsulant material configured to cover one or more LEDs, and/or coating on one or more optical or support elements (e.g., by powder coating, inkjet printing, or the like). In certain embodiments, lumiphoric materials may be downconverting or upconverting, and combinations of both downconverting and upconverting materials may be provided. In certain embodiments, multiple different (e.g., compositionally different) lumiphoric materials arranged to produce different peak wavelengths may be arranged to receive emissions from one or more LED chips. One or more lumiphoric materials may be provided on one or more portions of an LED chip in various configurations.

Light emitted by the active layer or region of an LED chip is initiated in all directions. For directional applications, internal mirrors or external reflective surfaces may be employed to redirect as much light as possible toward a desired emission direction. Internal mirrors may include single or multiple layers. Some multi-layer mirrors include a metal reflector layer and a dielectric reflector layer, wherein the dielectric reflector layer is arranged between the metal reflector layer and a plurality of semiconductor layers. A passivation layer is arranged between the metal reflector layer and first and second electrical contacts, wherein the first electrical contact is arranged in conductive electrical communication with a first semiconductor layer, and the second electrical contact is arranged in conductive electrical communication with a second semiconductor layer. For single or multi-layer mirrors including surfaces exhibiting less than 100% reflectivity, some light may be absorbed by the mirror. Additionally, light that is redirected through the active LED structure may be absorbed by other layers or elements within the LED chip.

In an embodiment, light emitted by the active layer or region of an LED chip may be unpolarized, where the electric or magnetic fields oscillate in a variety of orientations. The light emitted may also be multi-polarized, with some of the light being polarized in a variety of orientations, linearly, circularly, or elliptically.

As used herein, a layer or region of a light-emitting device may be considered to be “transparent” when at least 80% of emitted radiation that impinges on the layer or region emerges through the layer or region. Moreover, as used herein, a layer or region of an LED is considered to be “reflective” or embody a “mirror” or a “reflector” when at least 80% of the emitted radiation that impinges on the layer or region is reflected. In some embodiments, the emitted radiation comprises visible light such as blue and/or green LEDs with or without lumiphoric materials. In other embodiments, the emitted radiation may comprise nonvisible light. For example, in the context of GaN-based blue and/or green LEDs, silver (Ag) may be considered a reflective material (e.g., at least 80% reflective). In the case of ultraviolet (UV) LEDs, appropriate materials may be selected to provide a desired, and in some embodiments high, reflectivity and/or a desired, and in some embodiments low, absorption. In certain embodiments, a “light-transmissive” material may be configured to transmit at least 50% of emitted radiation of a desired wavelength.

The present disclosure can be useful for LED chips having a variety of geometries, such as vertical geometry or lateral geometry. A vertical geometry LED chip typically includes anode and cathode connections on opposing sides or faces of the LED chip. A lateral geometry LED chip typically includes both anode and cathode connections on the same side of the LED chip that is opposite a substrate, such as a growth substrate. In certain embodiments, a lateral geometry LED chip may be arranged for flip-chip mounting on another surface.

As used herein, light-altering materials may include many different materials including light-reflective materials that reflect or redirect light, light-absorbing materials that absorb light, and materials that act as a thixotropic agent. As used herein, the term “light-reflective” refers to materials or particles that reflect, refract, or otherwise redirect light. For light-reflective materials, the light-altering material may include at least one of fused silica, fumed silica, titanium dioxide (TiO₂), or metal particles suspended in a binder, such as silicone or epoxy. For light-absorbing materials, the light-altering material may include at least one of carbon, silicon, or metal particles suspended in a binder, such as silicone or epoxy. The light-reflective materials and the light-absorbing materials may comprise nanoparticles. In certain embodiments, the light-altering material may comprise a generally white color to reflect and redirect light. In other embodiments, the light-altering material may comprise a generally opaque or black color for absorbing light and increasing contrast.

Aspects disclosed herein relate to wire grid polarization structures for LED devices, including LED chips and LED packages. Polarization structures are commonly used in various applications to produce polarized light for a variety of purposes, including reducing glare for human and/or machine vision. Specific glare reduction may be achieved by rotating such polarization structures until glare is reduced for a particular viewing angle. In the context of machine vision, such as a camera, an external polarization structure may be mechanically rotated until suitable glare reduction is achieved.

According to aspects of the present disclosure, an LED device, such as an LED chip and/or an LED package, may be integrated with a wire grid light-polarization structure, thereby reducing reliance on conventional polarization structures that are external to light sources. In certain embodiments, a single LED package may include multiple LED chips that are individually addressable with respect to one another, and each of the LED chips may include a separate light-polarizing film configurated with a different light rotation. In this manner, the overall polarization of the LED package may be electronically controlled and/or dynamically tuned by selectively activating and/or deactivating certain LED chips or certain groups of LED chips.

In an aspect of the present disclosure, the polarization of the light can be facilitated by a wire grid structure. Wire grid polarizers are a class of polarizers that use fine metal wires to restrict E-field oscillation for s-polarized light. Fine metal wires typically are lithographically deposited on substrates, with the thickness or material depending on the operating wavelength range. For the component of light polarized parallel to the metal wires, the metal grid works like a typical metal surface as electrons are excited along the wire length. As a result, the component of light polarized parallel to the metal wires is almost completely reflected. In the case of the component of light polarized perpendicular to the metal wires, electrons can only be excited along with wire width, which is in the sub-micron range. Hence, most of the component of light polarized perpendicular to the metal wires is transmitted. Accordingly, the wire grid polarizer preferentially transmits light emitted from the LED chip that is polarized along a first direction relative to light polarized along other directions, wherein the first direction is based on an orientation of the wire grid polarization structure.

Wire grid polarizers offer several advantages over conventional polarizers. For instance, they are suited for applications that require a high extinction ratio and/or high acceptance angle. Wire grid polarizers also are inherently broadband and can be designed to operate across UV-Visible-IR spectrums by choosing appropriate substrates. Finally, wire grid polarizers have greater thermal stability and can operate under high temperature or high flux conditions.

In an aspect of the present disclosure, the wire grid polarizer structure can be electrically coupled to an electrode of the LED package to more evenly spread current across a top surface of the LED chip. Some of the layers of an LED chip may be of materials that possess low conductivity. For mesa-structure LEDs, current spreading in the top p-type layer may be very weak, owing to the high resistivity of the p-type top cladding layer. The current spreading ensures that the injected current is spread as evenly as possible across the surface near the active layer of the LED chip, thus improving light emission efficiency and evenness. Traditional current spreaders use thick metal layers of around 10 to 100 microns, which are too thick to layer over an LED chip as it blocks too much light. The wire grid polarization structure, however, uses wires that are less than 1 micron thick and so the double benefit of a polarizing structure and a current spreader can be achieved.

Polarization structures according to the present disclosure may refer to structures that are capable of receiving unpolarized light and providing polarized light that exits the polarization structures. As used herein, unpolarized light may refer to light that is a collection of randomly polarized light waves, whereas polarized light may refer to light that is provided with a particular polarization or geometrical orientation, such as a linear polarization, plane polarization, elliptical polarization, and/or a circular polarization.

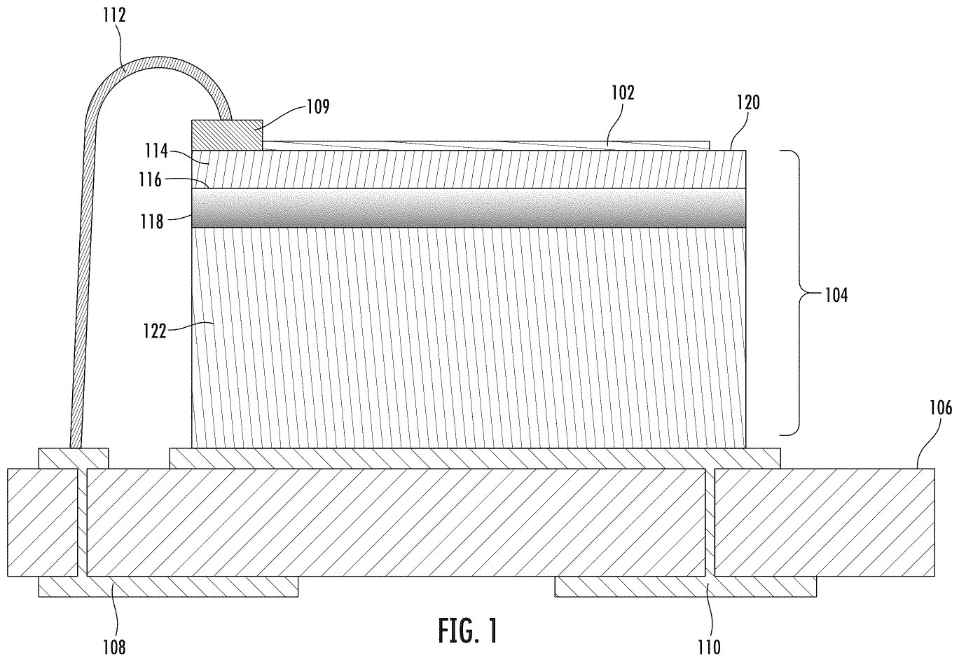

FIG. 1 is an exemplary cross-sectional diagram of an LED package with a wire grid polarization structure 102 according to one or more embodiments of the present disclosure.

The LED package can include electrodes 108 and 110 and a submount 106 on which an LED chip 104 is mounted. The LED chip 104 can include a substrate 122, and a first layer 114 and a second layer 118 with an active layer 116 between the first and second layers. The first layer 114 and the second layer 118 can be n-type or p-type oppositely doped epitaxial layers, each of which are formed successively over substrate 122. In one example, the first layer 114 is a p-type layer and the second layer 118 is an n-type layer. In another example, the order may be reversed such that the first layer 114 is an n-type layer and the second layer 118 is a p-type layer. The substrate 122 could be Si, GaAs, or even sapphire in various embodiments.

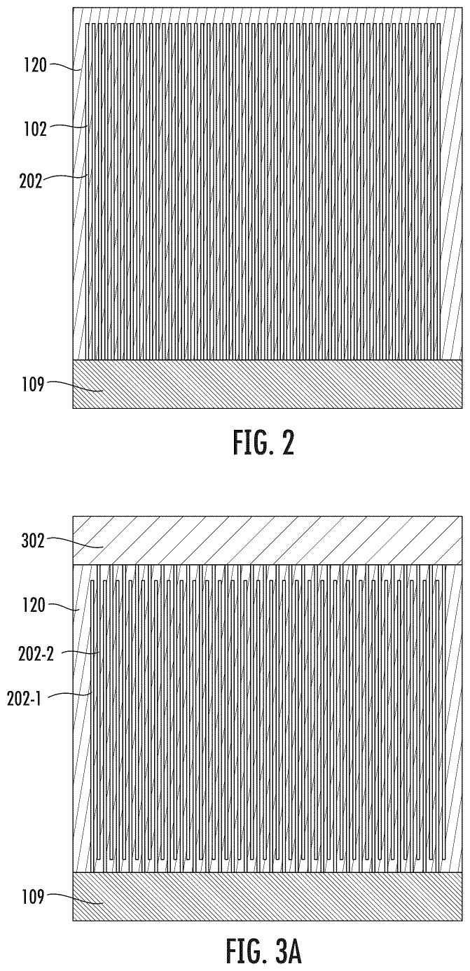

In an embodiment, a wire bond 112 can electrically couple an electrode 108 below the LED chip 104 to an electrode portion 109 of the wire grid polarization structure 102 on a top surface 120 of the LED chip 104. The wire grid polarization structure can include the electrode portion 109 as well as wires (e.g., 202 in FIG. 2) that facilitate the polarization and current spreading.

FIG. 2 is an exemplary top view of a wire grid polarization structure 102 coupled to a single electrode 108 according to one or more embodiments of the present disclosure.

In the embodiment shown in FIG. 2, the wires 202 of the wire grid polarization structure 102 extend out from the electrode portion 109 and cover the top surface 120 of the LED chip 104. The wires 202 can be in contact with the top surface 120 of the LED chip 104 and transfer current from the electrode portion 109 to the top surface 120 of the LED chip 104. The wires 202 can be between 0.04 and 1 micron thick and have an equivalent spacing between the wires. In an embodiment, the wire could have a cross-sectional width of 0.2 microns, with a distance between each wire also being 0.2 microns. A height of the wires 202 could be between 0.01 and 1 micron. In general, the ratio of heigh to width may be as high as 4. The pitch, or distance between wire centers may be based on the wavelength of the light emitted by the LED chip 104, but in general is around ⅓ of the wavelength, and so a pitch of 0.1-0.5 microns covers the visible and near infra-red ranges. A minimum thickness of the wires 202 could be around 40 nm The wires could be formed from one or more of gold, silver, or aluminum, depending on the wavelength of the LED chip 104. The wires 202 can be bonded or attached to the top surface 120 of the LED chip by an adhesion layer of chrome or titanium.

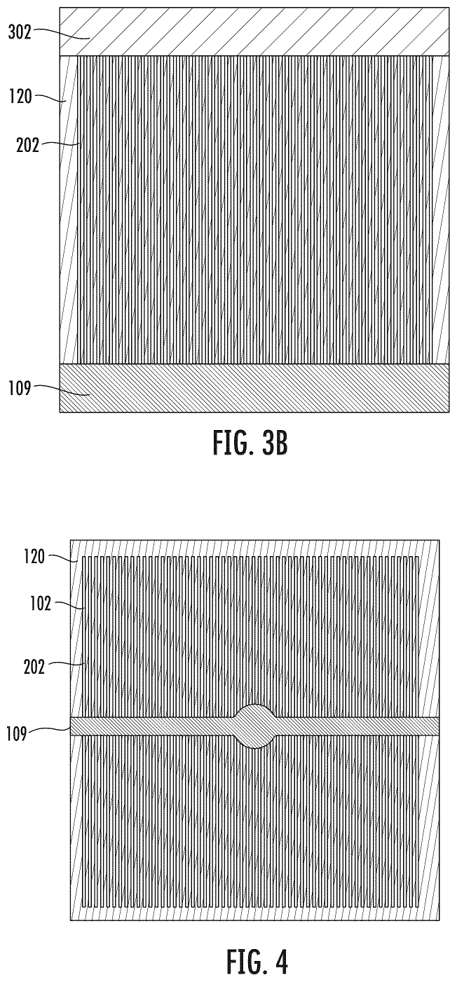

FIG. 3A is an exemplary top view of a wire grid polarization structure 102 coupled to two electrodes according to one or more embodiments of the present disclosure.

The wire grid polarization structure 102 can be coupled to two different electrodes (e.g., 108 and 110), and include electrode portions 109 and 302 coupled via wire bonds to the respective electrodes. The wires can be interdigitated, with wires 202-1 extending out from electrode portion 109 and wires 202-2 extending out from electrode portion 302, without intersecting. In this way, current can be more evenly spread out from both sides of the LED chip 104. The electrode portions 109 and 302 may also be coupled to the same epitaxial layer (e.g., first layer 114).

FIG. 3B is another top view of a wire grid polarization structure 102 where the wires 202 connect to each of electrode portions 109 and 302. The electrode portions 302 and 109 may be the same polarity, or different polarity in various embodiments. In an embodiment, and advantage of the embodiment in FIG. 3B over the embodiment in FIG. 3A is that the current spread by the wire grid polarization structure 102 can be more evenly distributed across the center of the LED chip 104 by having current flow from both sides of the wires 202.

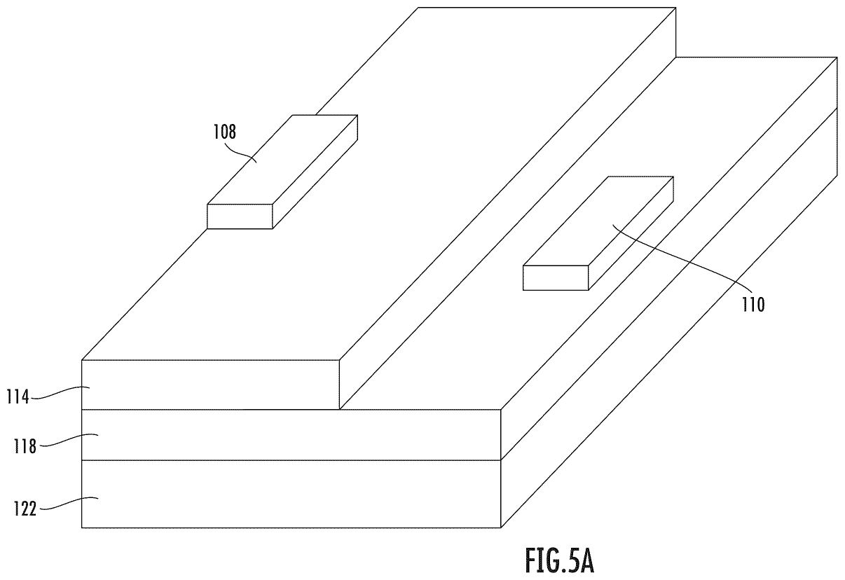

FIG. 4 is an exemplary top view of another wire grid polarization structure 102 coupled to a single electrode according to one or more embodiments of the present disclosure.

The embodiment in FIG. 4 is another configuration of a similar functional embodiment shown in FIG. 2, where the electrode portion 109 bisects a top surface 120 of the LED chip 104, and the wires 202 extend out from either side of the electrode portion 109. In an embodiment, and advantage of the embodiment in FIG. 4 over the embodiment in FIG. 2 is that the current spread by the wire grid polarization structure 102 can be more evenly distributed across the center of the LED chip 104 by starting in the middle, with less distance to travel to the edges of the LED chip 104.

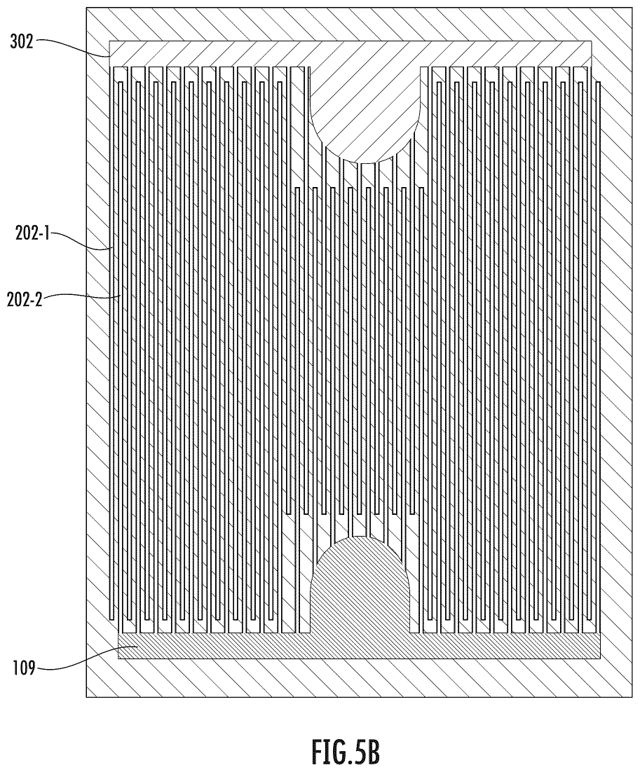

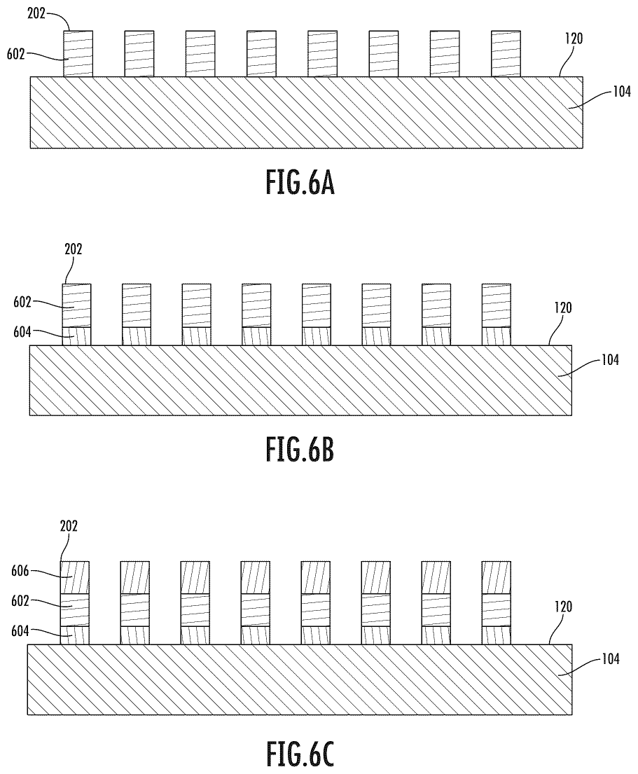

FIG. 5A is an exemplary isometric view of a lateral die LED with two electrodes 108 and 110 according to one or more embodiments of the present disclosure. In an embodiment, FIG. 5A shows a general 2 topside LED chip structure. In the embodiment shown in FIG. 5A, the first layer 114 and second layer 118 contacts are on the top and side of the LED chip 104 and the wire grid polarization structure 102 may spread the current from the electrode portions 108 and 110 across each layer.

In FIG. 5B, depicted is a wire grid polarization structure 102 in an implementation where electrode portion 302 and wires 202-1 form a contact to layer 118 from FIG. 5A, and electrode portion 109 and wires 202-2 form a contact to layer 114.

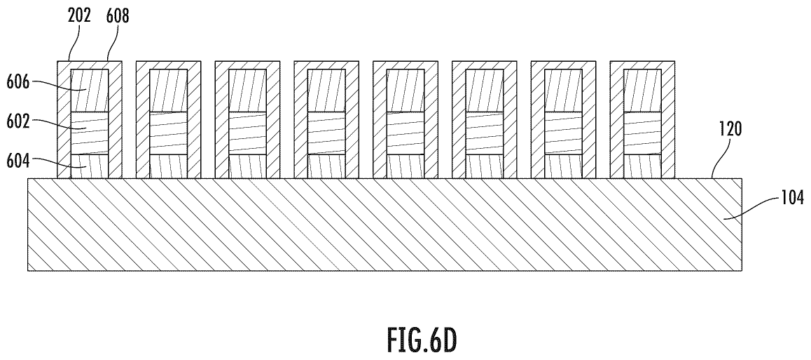

FIGS. 6A-6D are exemplary cross-sectional views of various embodiments of wire grid polarization structure wires 202 according to one or more embodiments of the present disclosure.

The wires 202 of the wire grid polarization structure 102 can lay across the top surface 120 of the LED chip 104 and have generally a uniform spacing and thickness that is selected based on the emission characteristics of the LED chip 104, and the desired polarization and current spreading characteristics. For example, while the metal used for the wires 202 can be silver, gold, or aluminum or other metals, gold doesn't polarize blue light well, but has superior current spreading characteristics.

In the embodiment depicted in FIG. 6B, the wires 202 can include an adhesion layer 604 that can help the wires 202 both adhere to the top surface 120 of the LED chip 104 as well as provide an electrical contact, to facilitate transfer of current from the wires 202 to the LED chip 104. The adhesion layer 606 could be chrome or titanium, or another metal.

In an embodiment, shown in FIG. 6A, the wire 202 can be formed from a single metal 602, whereas in FIG. 6C, the wire 202 can be formed from a combination of a first metal 602 and a second metal 606 and optionally the adhesion layer 604. While these metals are shown formed in horizontal layers, the metals may be mixed, alloys, or formed in different layering patterns. The metal selection and ratio can also control the complex refractive index (n and k) to further tune and control the polarization selectivity and wavelength.

In the embodiment shown in FIG. 6D, the wires 202 can include a passivation layer or dielectric layer 608 that provides protection of the wires from oxidation, moisture, and other external factors. While shown in the context of FIG. 6C, the passivation layer or dielectric layer 608 may also be implemented on any of the previous embodiments illustrated in FIGS. 6A and 6B.

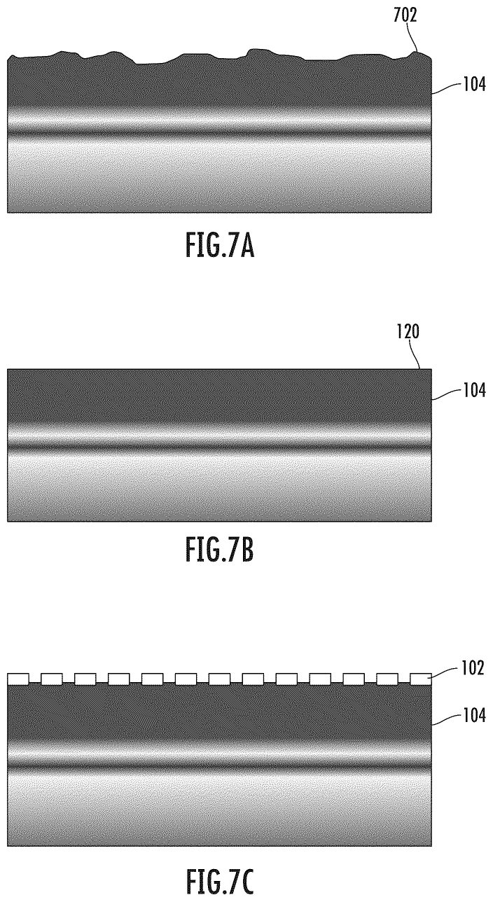

FIGS. 7A-7C are diagrams depicting planarization of an LED chip surface and wire grid polarization structure formation according to one or more embodiments of the present disclosure.

The top surface 120 of the LED chip can include variety of surface texture features 702. By way of example, the top surface 120 may be a top surface of the first layer 114 of FIG. 1. The surface texturing is commonly used to increase light extraction, but can interfere with the wire grid polarization structure because consistent ohmic contact should be made to help facilitate current spreading. Another issue is that a rough surface can cause light scattering which scrambles/randomizes the light polarization which can reduce the effectiveness of the wire grid polarizer. Therefore, the features 702 in FIG. 7A can be removed via planarization of the top surface 120, with the resulting smooth surface 120 shown in FIG. 7B. The planarization technique used can be a chemical mechanical planarization that results in surface features of less than 0.1 microns.

Chemical mechanical polishing (CMP) or planarization is a process of smoothing surfaces with the combination of chemical and mechanical forces. The process uses an abrasive and corrosive chemical slurry (commonly a colloid) in conjunction with a polishing pad and retaining ring. The dynamic polishing head is rotated with different axes of rotation (i.e., not concentric). This removes material and tends to even out any irregular topography.

Once the surface 120 has been planarized, the wire grid polarization structure can be formed as shown in FIG. 7C.

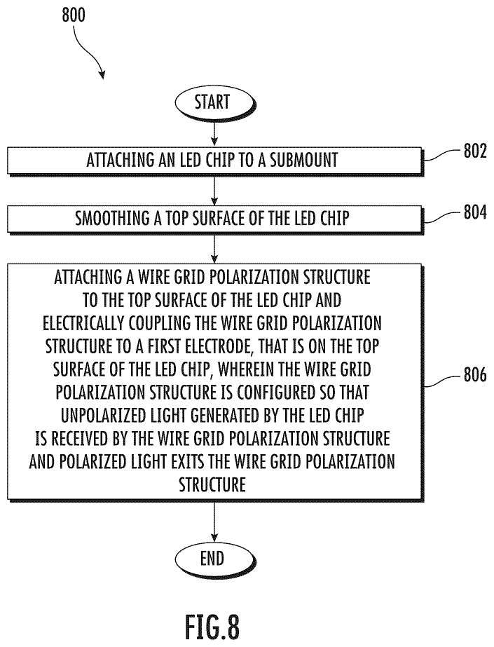

FIG. 8 is a flowchart of a method for forming an LED package with a wire grid polarization structure according to one or more embodiments of the present disclosure.

The method can begin at step 802 where the method includes attaching an LED chip to a submount.

At 804, the method includes smoothing a top surface of the LED chip. The smoothing can be performed via chemical mechanical planarization.

At 806, the method includes attaching a wire grid polarization structure to the top surface of the LED chip and electrically coupling the wire grid polarization structure to a first electrode, that is on the top surface of the LED chip, wherein the wire grid polarization structure is configured so that unpolarized light generated by the LED chip is received by the wire grid polarization structure and polarized light exits the wire grid polarization structure. In an embodiment, the wire grid polarization structure is configured to be a current spreading layer.

In an embodiment, a first portion (e.g., 202-1 and 109) of the wire grid polarization structure is electrically coupled to the first electrode, and wherein the method further comprises electrically coupling a second portion (202-2 and 302) of the wire grid polarization structure to a second electrode that delivers current to the top surface of the LED chip.

In an embodiment, the wire grid polarization structure can be formed from at least one of aluminum, silver, or gold.

In an embodiment, the method can include forming the wire grid polarization structure from at least two of aluminum, silver, or gold, wherein a ratio of the metals is predetermined based on a polarization selectivity or a wavelength of light emitted by the LED chip.

In an embodiment, the method can include applying an adhesion layer of chrome or titanium to the top surface of the LED chip before attaching the wire grid polarization structure.

In an embodiment, the method can include forming a passivation layer around the wire grid polarization structure.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) package, comprising:
a submount;
an LED chip on the submount;
a first electrode that delivers current to a top surface of the LED chip; and
a wire grid polarization structure, electrically coupled to the first electrode, that is on the top surface of the LED chip, wherein the wire grid polarization structure is configured so that unpolarized light generated by the LED chip is received by the wire grid polarization structure and polarized light exits the wire grid polarization structure.

2. The LED package of claim 1, wherein the wire grid polarization structure is configured to be a current spreading layer.

3. The LED package of claim 1, further comprising a second electrode that delivers current to the top surface of the LED chip, wherein the first electrode is electrically coupled to a first portion of the wire grid polarization structure, and the second electrode is electrically coupled to a second portion of the wire grid polarization structure.

4. The LED package of claim 3, wherein wires of the first portion of the wire grid polarization structure and wires of the second portion of the wire grid polarization structure are interdigitated.

5. The LED package of claim 1, wherein the wire grid polarization structure preferentially transmits light emitted from the LED chip that is polarized along a first direction relative to light polarized along other directions, wherein the first direction is based on an orientation of the wire grid polarization structure.

6. The LED package of claim 1, wherein the first electrode is electrically coupled to the wire grid polarization structure via a wire bond.

7. The LED package of claim 1, wherein the wire grid polarization structure is bonded to the top surface of the LED chip by an adhesion layer that is formed of at least one of chrome or titanium.

8. The LED package of claim 1, wherein wires of the wire grid polarization layer comprise at least one of aluminum, silver, or gold.

9. The LED package of claim 1, wherein wires of the wire grid polarization layer comprise at least two of aluminum, silver, or gold, wherein a ratio of the metals is predetermined based on a polarization selectivity.

10. The LED package of claim 1, wherein wires of the wire grid polarization layer comprise at least two of aluminum, silver, or gold, wherein a ratio of the metals is predetermined based on a wavelength of light emitted by the LED chip.

11. The LED package of claim 1, further comprising a passivation layer covering the wire grid polarization structure.

12. The LED package of claim 1, wherein wires of the wire grid polarization structure have a cross-sectional diameter less than 1 micron.

13. A method for forming a light-emitting diode (LED) package, comprising:
attaching an LED chip to a submount;
smoothing a top surface of the LED chip; and
attaching a wire grid polarization structure to the top surface of the LED chip and electrically coupling the wire grid polarization structure to a first electrode, that is on the top surface of the LED chip, wherein the wire grid polarization structure is configured so that unpolarized light generated by the LED chip is received by the wire grid polarization structure and polarized light exits the wire grid polarization structure.

14. The method of claim 13, wherein the wire grid polarization structure is configured to be a current spreading layer.

15. The method of claim 13, wherein a first portion of the wire grid polarization structure is electrically coupled to the first electrode, and wherein the method further comprises:
electrically coupling a second portion of the wire grid polarization structure to a second electrode that delivers current to the top surface of the LED chip.

16. The method of claim 13, further comprising:
forming the wire grid polarization structure from at least one of aluminum, silver, or gold.

17. The method of claim 13, further comprising:
forming the wire grid polarization structure from at least two of aluminum, silver, or gold, wherein a ratio of the metals is predetermined based on a polarization selectivity or a wavelength of light emitted by the LED chip.

18. The method of claim 13, further comprising:
applying an adhesion layer of chrome or titanium to the top surface of the LED chip before attaching the wire grid polarization structure.

19. The method of claim 13, further comprising:
forming a passivation layer around the wire grid polarization structure.

20. A light-emitting diode (LED) device, comprising:
an LED chip;
a first electrode that delivers current to a top surface of the LED chip; and
a wire grid polarization structure, electrically coupled to the first electrode, that is on the top surface of the LED chip, wherein the wire grid polarization structure is configured so that unpolarized light generated by the LED chip is received by the wire grid polarization structure and polarized light exits the wire grid polarization structure.
